(19) United States
(12) Patent Application Publication
(10) Pub. No.: US 2015/0086301 A1
(43) Pub. Date: Mar. 26, 2015

(54) METHOD AND CARRIER FOR HANDLING A SUBSTRATE

(71) Applicant: Applied Microengineering Limited, Didcot, Oxfordshire (GB)

(72) Inventors: Tony Rogers, Didcot (GB); Rob Santilli, Didcot (GB)

(73) Assignee: Applied Microengineering Limited, Didcot, Oxfordshire (US)

(21) Appl. No.: 14/402,866

(22) PCT Filed: Feb. 13, 2013
(86) PCT No.: PCT/GB2013/050336

§ 371 Date: Nov. 21, 2014

(30) Foreign Application Priority Data
May 20, 2012 (GB) 1209024.7

(51) Int. Cl. H01L 21/683

(52) U.S. Cl. CPC H01L 21/6838
USPC 414/217; 414/805

(57) ABSTRACT

There is disclosed a carrier and method for handling and/or transport of a substrate, such as during processing of the substrate, for example, back-thinning. The carrier and method provide support for the substrate. The process is particularly suited to thinning of substrates for use in 3D integrated circuits. The carrier comprises: a contact surface with one or more recesses therein for trapping a volume when the contact surface is brought towards the substrate, the contact surface for supporting the substrate; a sealing surface at the periphery of the contact surface and offset from the contact surface; and the sealing member seating on the sealing surface and arranged to be compressed to form a seal to the substrate when a substrate is in contact with the contact surface, the seal sealing the trapped volume between the substrate and carrier.

### TECHNICAL FIELD

The present invention relates to a method and carrier for handling a substrate for transport and/or processing. The method is particularly suited to handling and support of substrates where backside processing such as thinning is performed.

### BACKGROUND ART

There are many integrated circuit, MEMS, and III-V fabrication processes that require thinning of substrates or handling of thinned substrates or wafers. Substrates or wafers thinned to around 100 μm or less are fragile and may even be flexible such that during further processing steps they require support to prevent flexing or breakage.

Current techniques for providing structural rigidity require the substrate or wafer to be mounted on a temporary carrier during the thinning process or for post-thinning processing. The substrate or wafer is bonded to a carrier wafer using an adhesive. The adhesive is applied to the carrier wafer, such as by spinning on to the surface followed by a partial bake. The adhesive may for example be thermal cure or UV cure. The substrate or wafer is then aligned with the carrier, which is often of the same diameter, and the substrate and carrier brought together to achieve a bond. The carrier supports and protects the substrate during thinning or during processing steps after thinning.

A thinned wafer, for example <100 μm in thickness, will be easily damaged at its edge. The carrier wafer reduces the occurrence of such damage. Very thin substrates, such as ˜50 μm, become flexible and may therefore be difficult to process. The carrier maintains the substrate flat.

After processing, the thinned substrate is removed from the carrier. The removal of the adhesive after processing can be performed by heating the substrate and carrier to soften the adhesive. A special tool is used to slide the substrate from the carrier. Other methods of de-bonding the substrate from the carrier include immersion in solvent, UV release, laser lift-off, and thermal release via dissociation of the polymer adhesive. For solvent release it is preferable if the carrier is perforated to permit solvent ingress to the bond. For UV release the carrier must be transparent to UV so a transparent glass carrier may be used. For laser lift-off a laser is directed at the bonding interlayer. The interlayer absorbs energy from the laser causing it to be heated and the carrier and substrate dissociate. All of the methods for release of the adhesive bond require the equipment used and carrier to be cleaned after each use. It may also be necessary to remove excess adhesive during the bonding process. A further problem with using adhesive to bond the substrate to the carrier is that it is difficult to precisely control the thickness of the adhesive evenly across the carrier surface and maintain this even thickness as the substrate is brought into contact. If this unevenness is present when a substrate is sent for thinning the resultant thinned substrate may have a wedge profile with one side thicker than the other which may result in an unusable substrate.

As well as cleaning the tools, the substrate will also require cleaning. This unnecessarily subjects features on the surface of the substrate to further processing including solvent cleaning. Furthermore, the thinned wafer is likely to need support during this cleaning process. This is often provided by mounting onto a secondary carrier.

WO 2011/100204 (Hurley) describes an adhesive free method of carrier system. The system uses a wafer chuck on which is assembled a substrate or wafer. The system is particularly suited to the final clean of a substrate after thinning has been carried out. The wafer chuck comprises an enclosed reservoir and ports for connection to a vacuum pump. The wafer chuck has channels extending from the enclosed reservoir to a support surface. In use a substrate or wafer is assembled onto the support surface. A vacuum pump is connected to the one or more ports and the reservoir is pumped down to a reduced pressure or vacuum. The reduced pressure extends from the reservoir along channels to the support surface, where atmospheric pressure holds the substrate against the surface. For transport of the substrate and chuck pair the ports can be closed off to maintain the vacuum in the reservoir. After transport, and during processing, the ports can be reconnected to a pump and the vacuum in the reservoir refreshed. To provide the enclosed reservoir, the wafer chuck is bulky. The pump down process requires connection of ports to a pump. The ports themselves protrude from the chuck providing significant size. The protruding ports prevent use of the wafer chuck in many processing steps along the process line because wafer processing equipment cannot accommodate the ports. The arrangement is not suitable for use during backside grinding of a wafer. Furthermore, connection of pipes to the ports is time consuming and awkward. Hence, an improved method and/or device for handling of thin substrates and wafers is required.

US 2006/0179632 (Wilk) describes a semiconductor wafer support system in which a semiconductor wafer is loaded onto a first surface of a wafer support. The wafer support has a number of channels connecting with the first surface and extending through to an opposing second surface of the wafer support. The wafer and wafer support are placed in an environment at reduced pressure. A membrane is attached to the second surface to trap the reduced pressure in the channels and hold the wafer against the wafer support when the pair is moved to a higher pressure environment. Removal or piercing of the membrane releases the trapped pressure releasing the wafer from the support wafer. Difficulties with this method include attachment of the membrane while the wafer and support wafer are in a vacuum chamber.

JP 2005-175207 (Ishihara) discloses a system and method for reinforcing a semiconductor wafer during back-thinning. The system comprises a support having internal cavities. The semiconductor wafer is held to the support again by a reduced pressure trapped in the cavities. The semiconductor wafer has a layer adhered to the front surface. The layer aids the sealing of the cavities. The layer is attached by an adhesive layer. Difficulties with this method are found in removal of the adhesive. Furthermore, static friction or stiction holds the semiconductor wafer and support together strongly, causing a much reduced external pressure to be required for release.

US 2005/0115679 (Kurosawa) discloses an apparatus for holding a substrate when surface treatment is carried out to a back surface of the substrate. The apparatus includes at least one enclosed space defined by a cavity. An O-ring contacts with a front surface of the substrate. The apparatus is constructed so that the substrate is held against the apparatus using a difference between a trapped negative pressure and atmospheric pressure. This is achieved by decompressing the enclosed space in a decompression chamber and then removing the substrate and apparatus to atmospheric pressure.

### SUMMARY OF THE INVENTION

The present invention relates to a method of providing an on-board vacuum to temporarily hold and support a substrate to a carrier for processing and/or transport without needing ports for connection to a vacuum pump, and without the use of an adhesively attached sealing layer. Furthermore, the carrier may be shaped and sized to correspond to that of the substrate. The present invention also provides a carrier for use in the method.

The carrier for handling and/or transport of a substrate, such as during processing of the substrate, comprises: a contact surface with one or more recesses therein for trapping a volume when the contact surface is brought towards the substrate, the contact surface for contacting and supporting the substrate; a sealing surface at the periphery of the contact surface and offset from the contact surface; and the sealing member seating on the sealing surface and arranged to be compressed to form a seal to the substrate when a substrate is in contact with the contact surface, the seal sealing the trapped volume between the substrate and carrier. The sealing surface may be offset from the contact surface such as by a step or by being stepped back from the contact surface.

The sealing surface is preferably a polished surface. The sealing surface preferably has an average roughness, Ra, of less than 100 nm. Etched surfaces may also provide a suitably low average roughness. 50, 20 or 10 nm are preferable, but the lower roughness values are more easily obtained by polishing. A polished wafer may preferably have an average roughness of less than 1 nm to provide a long lasting vacuum suitable for the majority of processing durations including shipment overseas for processing. The lower the roughness value, the longer the sealed vacuum can be maintained.

The carrier may be formed of a first carrier wafer and a second carrier wafer of a greater diameter than the first carrier wafer, the second carrier wafer being bonded to the first to provide the sealing surface at the periphery of the first carrier wafer. The sealing surface may be formed of the polished surface of the second carrier wafer.

The offset between the contact surface and sealing surface may be a step.

The sealing member may be resilient, such that it returns back to its original shape after use so that it can be used again.

The sealing member is preferably endless, such as circular, but is not limited to a circular shape.

The sealing member may be a ring with a circular cross-section, such as an o-ring. Suitable materials for the sealing member are Viton, neoprene, EPDM, and nitriles, but Viton is preferred for vacuum integrity.

The sealing member may be inset from the edge of the carrier such that notches or flats in the circumference of a substrate to be processed are located peripheral to the sealing member. The dimensions of the notches or flats are defined by SEMI standards. For example, a 76 mm (3 inch) diameter substrate has a primary flat length of 22 mm which results in the edge of the substrate being cut back from circular by up to 1.7 mm such that the line of contact of the sealing member must be inset from a circle by at least this amount for the region of the flat. A 150 mm (6 inch) has a primary flat length of 57.5 mm which results in the line of contact of the sealing member being inset from a circle by at least 5.7 mm for the region of the flat. 300 mm (12 inch) substrates tend to have a 1 mm depth notch cut into the circumference, which result in the sealing member being inset from the edge by 1 mm at this point. Alternatively, the O-ring may be shaped to correspond to the perimeter of the wafer, for example to include a straight region that corresponds to the wafer flat, or a u-shaped region to correspond to a wafer notch.

The carrier may further comprise a support member located peripheral to the sealing member, for example, on the sealing surface. The support member is for supporting the edge of a substrate such as may be overhanging beyond the sealing member. In an alternative arrangement the sealing member and support member may be formed as one, such that effectively the sealing member is arranged to have a width to support the substrate from its edge to the seal.

The support member may be a ring.

The support member may be transparent at least for a size matching a notch or flat in the substrate, so that the notch or flat is not obscured for viewing by a machine vision systems operating by locating the edge and flat of the substrate. Alternatively, the support member may have a gap or aperture sized to match a notch or flat in the substrate so that the notch or flat is not obscured.

The support member may have a cross-section with a flat surface for supporting an edge region of the substrate. The support member may be resilient.

The carrier may be further shaped to provide a projection to retain the sealing member, such as a projection at edge of first carrier wafer forming carrier. The sealing member may be tensioned so as to be retained by the projection.

The offset between the contact surface and sealing surface may be formed by a step and the wall of the step may comprise the projection, such as a chamfer.

The support member may be shaped to at least partly engage with the sealing member so as to retain the support member.

The support member may be of a softer material, or if made from the same material as the sealing ring, then it can be designed such that it is more readily compressed than the sealing member, such that compression of the sealing member limits or defines the compression of the support member.

The first carrier wafer may be polished and the second carrier wafer may be patterned with recesses. The first carrier wafer and second carrier wafer are preferably of the same material or of substantially thermally expansion matched materials. The first carrier wafer is patterned or etched to include further recesses or cavities for accommodating device features/topography of the substrate to be processed.

For thinning and other processing steps for silicon substrates, the first carrier wafer and second carrier wafer may be formed of one or more of silicon and/or of glasses: Schott BF33, MemPax, Corning 7740 and Hoya SD2, or other glass, semiconductor or ceramic which is thermal expansion matched to silicon.

Alternatively, for thinning and other processing steps for III-V substrates, for example GaAs, the first carrier wafer and second carrier wafer may be formed of one or more of the III-V materials, for example GaAs, and/or glass, other semiconductor or ceramic which is thermal expansion matched to GaAs or other III-V material.

In a further alternative, namely for thinning and processing of II-VI substrates, the first carrier wafer and second carrier wafer are formed of one or more of a II-VI compound and/or glass, other semiconductor or ceramic which is thermal expansion matched to a II-VI compound. Said compound being the same or expansion matched to the substrate to be handled.

As an example, namely for thinning or processing of InP substrates the first carrier wafer and second carrier wafer are formed of one or more of InP and/or glass, other semiconductor or ceramic which is thermal expansion matched to InP.

The thermal expansion match is over the range of process temperature the carrier will experience such as up to 300 or 400° C.

The first and second carrier wafers are preferably bonded together without using an interlayer, for example by anodic or direct bonding.

The first and second carrier wafers may alternatively be bonded together by thermocompression, solder, eutectic, glass frit, or adhesive.

The carrier may comprise a passivation layer coating on surfaces such as to avoid the carrier material being etched when the substrate goes through further processing such as etching. If the carrier is made of silicon then suitable passivation can be provided by an oxide layer, nitride layer, or oxy-nitride layer, all of which can be readily created using standard semi-conductor processing techniques.

The present invention provides a method of handling a substrate or wafer for processing, namely temporary bonding of the substrate to a carrier without adhesive, the method comprising: loading the substrate into a chamber; loading a carrier into the chamber, the carrier having one or more recesses or cavities in a planar surface thereof; reducing the pressure in the chamber to a first pressure P1 or vacuum; moving at least one of the substrate and carrier to bring the contact surface of the carrier towards the substrate to trap a volume at the first pressure in the one or more recesses between the carrier and substrate; holding the substrate and carrier together to maintain the trapped reduced pressure in the one or more recesses while increasing the pressure in the chamber to a second pressure higher than the first; and releasing the hold on the substrate and carrier, the trapped reduced pressure holding the carrier and substrate together for processing. The second pressure may be atmospheric pressure. The method has advantages in that no adhesive is used to hold the carrier and substrate together so no cleaning steps for the carrier or substrate are required after the release step. Furthermore, the carrier and substrate contain the reduced pressure without the need for supply ports.

In an alternative embodiment the recesses may be formed in the substrate. However, this arrangement provides limitations on the use and patterning of parts of the substrate and so it is preferable to form the recesses in the carrier.

The substrate may be a semiconductor wafer such as a silicon wafer, a III-V wafer such as GaAs or InP, or even a II-VI wafer. Alternatively, the substrate may be sapphire, glass or other materials etc. The carrier may be formed of a semiconductor wafer, such as a silicon wafer. Alternatively, the carrier may be formed of glass or sapphire. The carrier may be the same material as the substrate or different. This will depend on the durability of the substrate material concerned and the temperature range that the post processing requires.

The sealing member is preferably seated on a sealing surface of the carrier offset, or stepped back from the contact surface and during the step of moving at least one of the substrate and carrier to bring them into contact with each other the sealing member may be compressed to form a seal to the substrate and sealing surface to maintain the trapped volume.

The sealing member may be inset from the edge of the carrier and during the step of moving at least one of the substrate and carrier the substrate may be aligned to the carrier such that notches or flats in the circumference of the substrate are located peripheral to the sealing member.

The carrier may comprise a support member located peripheral to the sealing member, for example, on the sealing surface, or other peripheral surface, for supporting the edge of a substrate, and during the step of moving at least one of the substrate and carrier the support member may be compressed when the sealing member is compressed.

The offset between the contact surface and sealing surface may be a step and the wall of the step may comprise a projection, and during release of substrate and carrier from each other the projection retains the sealing member.

The support member may at least partly engage with the sealing member such that during release of substrate and carrier from each other the sealing member retains the support member.

The method may be performed on a substrate on which processing of a first surface, such as device and/or solder bump formation, has already taken place. This first side processing may comprise: performing a first processing step or steps before the step of moving at least one of the substrate and carrier such that they come together. The first processing step or steps may include lithographic fabrication of devices and/or solder bumps. In the step of moving at least one of the substrate and carrier the first surface is arranged to face the carrier. After the step of releasing, performing a second processing step, such as grinding or lapping on a second surface of the substrate opposing the first. The first surface is the front side of the substrate and the second surface is the back side.

During the second processing step the substrate may be handled by contact with the carrier only.

The second processing step may be thinning of the substrate.

The method may further comprise debonding of the substrate from the carrier, comprising: loading the substrate and carrier into a chamber; and reducing the pressure in the chamber to a third pressure lower than the first pressure, such that the substrate and carrier are released from each other.

The carrier may comprise a sealing layer on at least part of the contact surface as an alternative to the sealing member. The sealing layer may comprise a compliant material, such as silicone. Alternatively, the sealing layer may comprise photoresist. However, preferably the sealing layer is compliant material that does not adhere to the carrier or substrate.

The step of holding may comprise applying a force to hold the substrate and carrier to maintain the trapped reduced pressure while the pressure in the chamber is increased. The force may be mechanical or electrostatic.

The step of loading the carrier into the chamber may comprise clamping the carrier to a first platen facing downwards towards a second platen, and the step of loading the substrate into the chamber may comprise placing the substrate onto the second platen below the first platen. Alternatively, the loading can be done at any orientation. However, since the subsequent debond step, whereby we need to release the substrate, works most conveniently if the carrier is fixed to the upper platen with the substrate facing downwards, it may be preferable to perform the bond step using the same orientation such that there is no need to change the tooling orientation.

Prior to the step of reducing the pressure to a third pressure, one of the carrier and substrate may be held on a first platen above but facing down to a second platen, such that upon release the other of the substrate and carrier are received by the second platen below the first platen. The carrier may be clamped to the first platen.

The recesses in the carrier may be aligned with protruding topographic features on the substrate.

The present invention further provides a method of handling a substrate and carrier after a processing step on the substrate has been performed, wherein the carrier comprises recesses trapping a volume at a pressure lower than the surrounding pressure to hold the substrate to the carrier, the method debonding the carrier and substrate comprising: loading the substrate and carrier into a chamber; and reducing the pressure in the chamber to a pressure lower than the trapped pressure, such that the substrate and carrier are released from each other. The steps of debonding may be performed at a different location to the bonding steps.

The present invention further provides a method of handling a substrate for processing, the method comprising: heating a substrate and carrier to a first temperature,

the carrier having one or more recesses or cavities in a contact surface thereof; moving at least one of the substrate and carrier to bring the contact surface of the carrier towards the substrate to trap a volume at the first temperature in the one or more recesses between the carrier and substrate; holding the substrate and carrier to maintain the trapped volume in the one or more recesses while reducing the temperature of the carrier and substrate to a second temperature, the trapped volume cooling to a reduced pressure; and releasing the hold on the substrate and carrier, the trapped volume holding the carrier and substrate together for processing.

The method may further comprise: performing a processing step on the substrate; heating the substrate and carrier to a third temperature higher than the first such that the substrate and carrier are released from each other; and cooling the substrate and carrier.

The present invention also provides a method of handling a substrate and carrier after a processing step on the substrate has been performed, wherein the carrier comprises recesses trapping a volume to hold the substrate to the carrier, the method comprising: heating the substrate and carrier to a temperature higher than that at which the volume was trapped in the recesses such that the substrate and carrier are released from each other; and cooling the substrate and carrier.

The present invention provides a carrier for handling and/or transport of a substrate, the carrier having a contact surface with one or more recesses therein for trapping a volume when the contact surface is brought towards a substrate, the one or more recesses comprising closed channels such when the contact surface is in contact with a substrate the recesses are closed and no volume flow occurs through the recesses. By closed channels or recesses formed in the contact surface, we mean channels or recesses that do not extend through to another surface such as an internal cavity or opposing surface of the carrier. The contact surface may comprise a compliant material for sealing a vacuum. The carrier may be formed of a semiconductor wafer and the channels are fully closed by the semiconductor wafer and compliant layer, if present, alone.

The present invention comprises methods of bonding using a vacuum or heating the carrier and substrate. These methods may be combined such that bonding is performed using one of a heat or pressure based method and debonding is performed using the other of the heat or pressure technique.

Also the bonding step can be performed using a combination of heat and reduced pressure, and the debonding step can also be performed using a combination of heat and reduced pressure. As long as the combination of heat and reduced pressure during the bonding step results in a pressure for the trapped volume that is lower than atmospheric pressure then the bonding step will be successful. Further, provided that the combination of heat and reduced pressure for the debonding step results in a pressure for the trapped volume that is less then the equivalent pressure used in the bonding step, then the debonding will be successful.

The present invention further provides apparatus for mounting a substrate to a carrier for handling and/or transport of the substrate, such as during processing of the substrate, the apparatus comprising: an upper platen and a lower platen arranged in a chamber, the chamber configured to be evacuated to a vacuum or pressure lower than atmospheric; the upper platen is arranged facing downwards above the lower platen, and is arranged to hold a carrier; the lower platen is arranged to receive a substrate; the upper or lower platen is movable up and down relative to the other platen such that the platens can be brought towards each other so as to bring carrier and substrate into contact, wherein at least one of the platens is arranged for movement in a lateral and/or rotational direction for alignment of the substrate and carrier. In an alternative the carrier and substrate may be swapped such that the upper platen is adapted to receive the substrate and the lower platen is adapted to receive the carrier.

The apparatus may further comprise an imaging system for viewing or imaging carrier and substrate as they aligned and are brought into contact with each other.

The carrier may be provided with alignment marks for viewing during alignment of substrate and carrier.

At least one of the platens may comprise holes or optically transparent windows for viewing the carrier held by the upper platen and a surface of the substrate.

The imaging system may operate using infra-red and/or visible light.

The chamber may comprise a transparent window for viewing a carrier held by one of the upper platen and lower platen and a surface of a substrate on the other of the upper and lower platen.

The chamber may comprise the camera of the imaging system.

At least one of the platens may comprise a heater for increasing the temperature of a carrier and substrate so as to increase the pressure of a volume trapped in recesses between the carrier and substrate.

### BRIEF DESCRIPTION OF THE DRAWINGS

Embodiments of the present invention will now be described with reference to the accompanying drawings, of which:

FIG. 1a is schematic diagram through a diametric cross-section of a carrier;

FIG. 1b is a plan-view of the carrier of FIG. 1a;

FIG. 1c is a plan-view of an alternative embodiment of recesses in carrier of FIG. 1a;

FIG. 2 is a schematic diagram of a bonding chamber;

FIG. 3 is a schematic diagram of a substrate and carrier pair in cross-section;

FIG. 4 is a schematic diagram of a substrate and carrier pair in cross-section, including a compliant bonding layer;

FIG. 5 is a flow chart listing the steps to bond a substrate and carrier pair;

FIG. 6 is a flow chart listing the steps to debond a substrate and carrier pair;

FIGS. 7a and 7b schematically show another embodiment of the carrier which comprises an o-ring sealing member with the substrate being brought into contact with the carrier;

FIG. 8 is an enlarged view of sealing member and surrounding region as identified by “C” in FIG. 7b;

FIGS. 9 to 11 are enlarged views corresponding to FIG. 8 and further including a support member according to different embodiments;

FIG. 12 is an enlarged view corresponding to FIG. 10 including a shaped edge of the carrier to retain the sealing member;

FIG. 13 is an enlarged view corresponding to FIG. 12 where the support member is also shaped for retention; and

FIG. 14 is a schematic illustration of the apparatus of FIG. 2 additionally including an alignment system.

### DETAILED DESCRIPTION

There are many integrated circuit, MEMS, and III-V fabrication processes that require thinning of substrates or handling of thinned substrates or wafers during processing. For example, after fabricating devices on a front side of a wafer or substrate it is often necessary to perform processing on the back side of the wafer or substrate. For example, back side thinning. Conventional techniques bond the wafer or substrate to a carrier using adhesive. The wafer or substrate is then debonded from the carrier after backside processing has been performed.

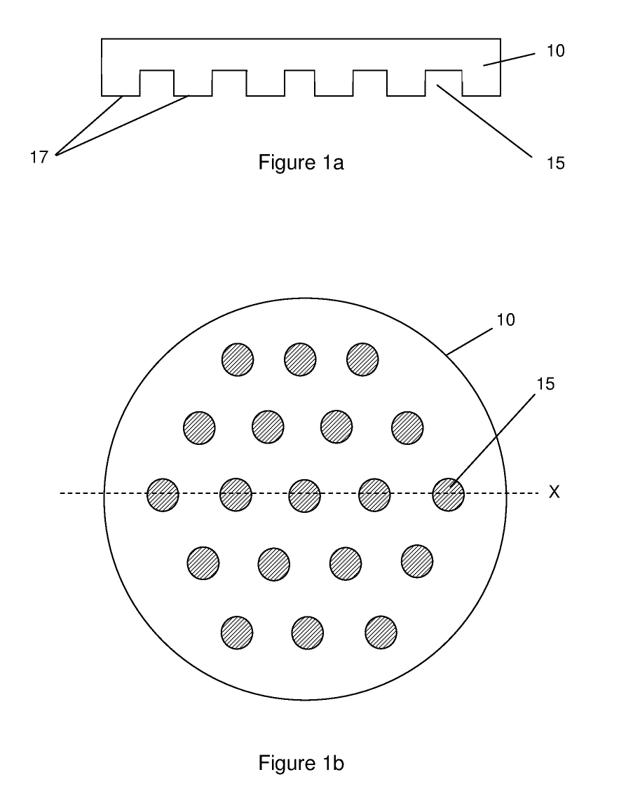

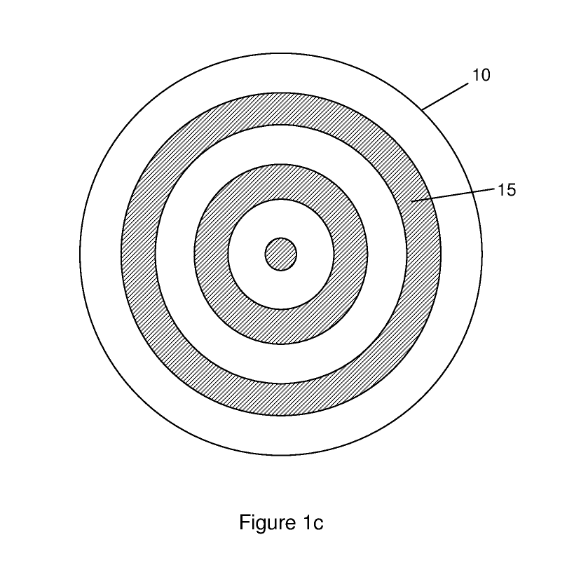

FIGS. 1a and 1b show a carrier 10 for supporting a wafer or substrate during processing. In the following discussion we use the term wafer or process wafer, which normally refers to a semiconductor substrate, but other substrates such as glass may also be processed in this way.

The carrier 10 is of similar plan dimension to a process wafer to be processed or handled. For example, as shown in FIG. 1b the carrier may be circular. Line X in FIG. 1b represents the line of the cross-section shown in FIG. 1a. The carrier is preferably of the same diameter as the process wafer to be processed or handled. The carrier may be a substrate of identical material to the wafer to be processed. Hence, for a silicon wafer to be back-thinned, the carrier may be a silicon wafer of full thickness such as 500 μm for a 100 mm diameter wafer or 700 μm for a 200 mm diameter wafer. The carrier 10 is provided with recesses 15 in one of the planar surfaces thereof. The planar surface with recesses, or contact surface 17, will be assembled to the process wafer for handling. The recesses may be formed in the carrier by well-known techniques such as etching, or by physical abrasion processes such as powder blasting. As shown in FIG. 1b, the recesses are a series of cavities arranged across the contact surface 17. The recesses may be arranged to match high spots on the process wafer such as solder balls. The carrier may have recesses arranged specifically for the layout of a process wafer. By aligning the recesses with the high spots the process wafer will be able to sit flat against the contact surface of the carrier. As shown in FIG. 1b, the cavities are circular but other shapes and arrangements may be used such that they correspond with high points or raised features on the process wafer.

In an alternative arrangement, shown in FIG. 1 c, the recesses are concentric rings. The diameters of the rings are in a range such that the rings are spread across the contact surface.

The carrier 10 may alternatively be made from a metal preferably having a coefficient of thermal expansion matched to that of the wafer. For example, Kovar (RTM) and Invar are respectively approximately matched to GaAs and silicon.

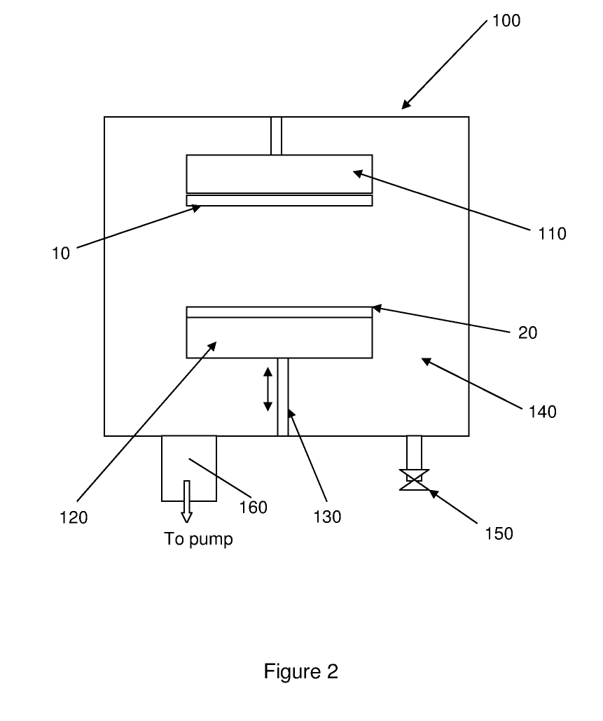

FIG. 2 schematically shows an apparatus 100 for “bonding” the carrier 10 and process wafer 20. The apparatus includes an upper platen 110 and lower platen 120 arranged in a vacuum chamber 140. The upper platen 110 is arranged facing downwards above lower platen 120. The upper platen 110 is arranged to hold the carrier 10 such as by clamping. The clamp is a 3-point edge clamp, but other ways of holding the carrier are possible such as electrostatic chuck. The lower platen 120 is arranged to receive the process wafer 20. No clamping is necessary because the force of gravity will hold the process wafer on the lower platen 120. At least one of the platens is movable up and down such that the platens can be moved together. In FIG. 2, the lower platen 120 is provided with a vertical drive mechanism 130 to lift the lower platen upwards. This direction is commonly referred to as the z-direction and the up-down movement as z-drive. Other arrangements of platen and drive direction are possible. For example the upper platen could be arranged to move downwards.

The vacuum chamber 140 is provided with two ports. The first port 160 provides a connection to a pump for reducing the pressure in the chamber, such as pumping the chamber down to a partial vacuum. The other port 150 is a vent valve which allows the pressure in the chamber to be increased, such as back to atmospheric pressure. The vent valve may alternatively be connected to a gas source such as an inert or non-reactive gas. The vent valve 150 is arranged to allow gradual release of the reduced pressure or vacuum in the chamber to pressure other than atmosphere.

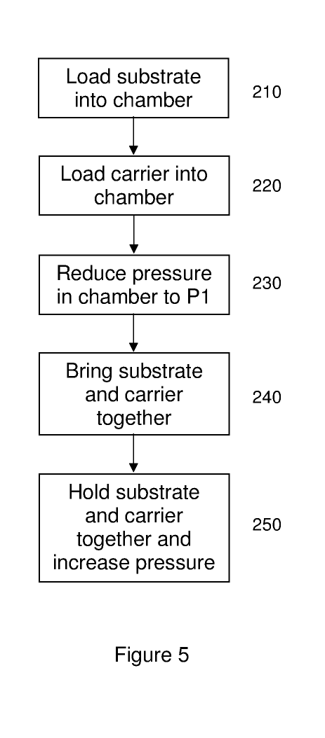

FIG. 5 is a flow chart showing the steps of the method for “bonding” the carrier and process wafer for processing or handling. By the term “bonding” we use the term of art in which a physical adhesive bond is formed between the wafer and carrier. However, in the method which follows no adhesive compound is used.

After opening the chamber, the carrier 10 and process wafer 20 are loaded into the chamber at steps 210 and 220. The carrier 10 is mounted to the upper platen 110 and held to the platen by the clamps. The process wafer 20 is loaded onto the lower platen 120. As mentioned above the arrangement of platens, process wafer and carrier may be different. For example, the carrier 10 may be placed on the lower platen 120 and the process wafer 20 on the upper platen. It is preferable that the process wafer 20 is on the lower platen 120 as this avoids having to apply clamps to the wafer which might cause damage to the edge of the wafer.

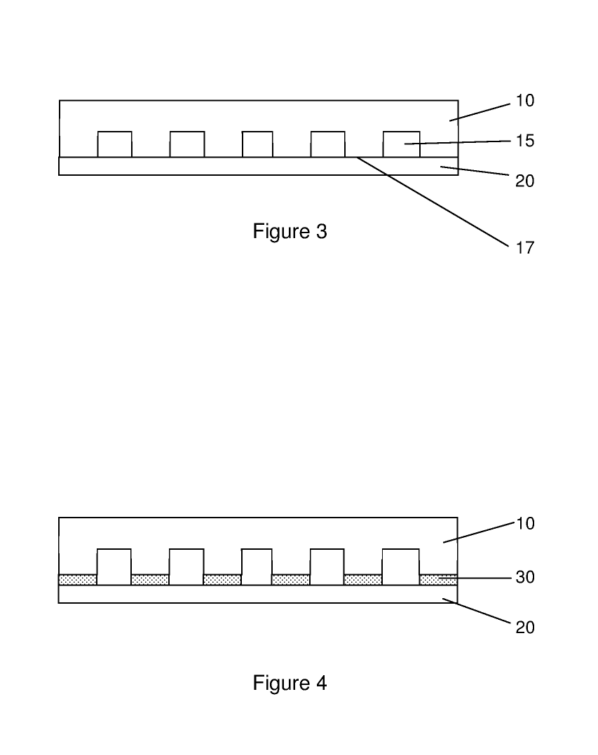

After loading the process wafer 20 and carrier 10, the chamber 140 is pumped down to reduced pressure at step 230. Details of how much the pressure is to be reduced are discussed later. After reducing the pressure in the chamber, the lower platen 120 carrying the process wafer 20 is raised upwards by actuating the z-drive 130. The platen 120 is raised until the process wafer 20 is brought into contact with the carrier 10, as indicated at step 240. The carrier 10 and process wafer 20 are in contact as shown in FIG. 3, with the recesses 15 in the contact surface 17 trapping a reduced pressure.

Step 250 of FIG. 5 indicates the final steps are to apply a force to hold the process wafer 20 and carrier 10 together while the pressure in the chamber is increased. After increasing the pressure, the applied force can be removed. The higher pressure outside of the process wafer and carrier pair forces the carrier and process wafer together. Using the apparatus of FIG. 2, the applied force may be provided by the z-drive 20 on the lower platen 120.

If the carrier and process wafer pair are to be removed from the chamber, the pressure in the chamber is raised to atmospheric pressure. In some embodiments the carrier and process wafer pair undergo further processing in the same apparatus, or are transferred under reduced pressure to other equipment for further processing. In such cases, the pressure is still raised but is not raised to atmosphere. The sealed process wafer and carrier pair are removed from the chamber after the pressure has been raised.

The carrier 10 provides rigidity and support to the process wafer 20 during further processing. Examples of further processing include lapping, polishing and grinding, or the formation of vias. Lapping, polishing and grinding can be performed with reduced risk of fracture and especially at the edges of the process wafer 20. Vias can be made through the process wafer 20 with reduced risk of fracture across the wafer because of the support provided by the carrier. These process steps are performed on the back side of the process wafer 20. For example, after production of ICs on the front side, the wafer remains too thick for the intended application which might include the need to dissipate heat rapidly, or to form part of a 3D integrated device. A more detailed discussion of vias is provided later.

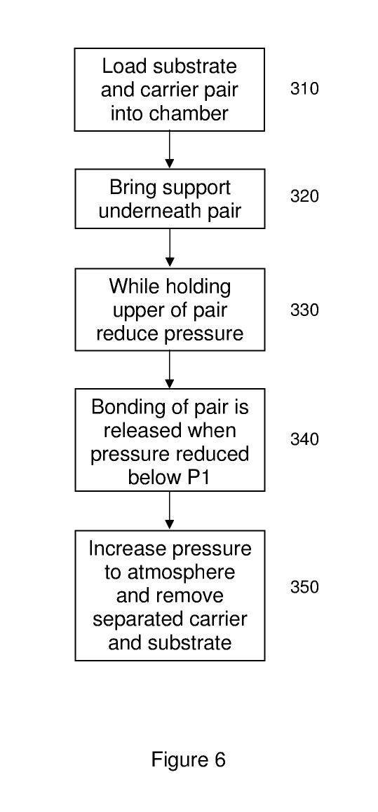

After the backside processing steps are completed the process wafer 20 can be removed from carrier 10. The same apparatus, shown in FIG. 2, as for sealing the process pair together can be used to separate them. The steps for separation are listed in FIG. 6. Firstly at step 310 the sealed pair is loaded into the apparatus 100. The pair is loaded into the upper platen 110 with the carrier 10 held by clamps to the platen 110 and the process wafer 20 on the downward side of the pair. Alternatively the process wafer 20 may be clamped to the platen but it is preferable to apply the clamps to the carrier 10 so as not to damage the process wafer 20. The next step, at 320, is to bring the lower platen up close to the sealed pair. This is achieved by actuating the z-drive to move the lower platen 120. Once the lower platen 120 is in close proximity, such as 100 μm or 50 μm (in principle any distance can be used for dropping the process wafer onto the lower platen but as the distance increases the risk of damage becomes greater) away from the lower surface of the process wafer 20, the pressure in the chamber 140 is reduced, as indicated at step 330. The pressure should be pumped down until the pressure is below that which was previously trapped in the recesses (less than P1, see step 230) for sealing the pair together. At step 340, the process wafer 20 is released as the higher pressure trapped in the recesses forces the process wafer 20 from the carrier 10. The process wafer 20 will drop onto the lower platen 120.

Static friction or stiction between the process wafer 20 and carrier 10 will hold the process wafer and carrier together to a pressure below P1 so the reduced pressure needed for release will be slightly less than P1. After release the pressure in the chamber 140 can be increased back to atmosphere, such as by venting valve 150 and the carrier and process wafer removed form the chamber, as indicated at step 350.

The carrier 10 is not damaged and does not require cleaning after step 350 so it may be left in the apparatus 100 for the next process wafer to be received.

Table 1, which follows, shows the mass that can be supported by a 1 mBar and 100 mBar pressure differential in the recesses compared to outside of the sealed pair. The mass that can be supported is compared to the mass of silicon wafers of standard sizes.

TABLE 1
comparison of mass of process wafers with mass supported
by 1 mBar and 100 mbar pressure differential (Vacuum
area based on 50% of wafer area).

| | | | | Maximum | Maximum |
|---|---|---|---|---|---|
| | | | | process | process |
| | | | | wafer mass | wafer mass |
| | | Mass of | Vacuum | supported | supported |
| Wafer | Wafer | process | area of | by 1 | by 100 |
| diameter | thickness | wafer | carrier | mBar ΔP | mBar ΔP |
| (mm) | (mm) | (g) | (cm2) | (g) | (g) |
| 100 | 0.525 | 9.5 | 39.3 | 39.3 | 3928 |
| 150 | 0.675 | 27.4 | 88.4 | 88.4 | 8837 |
| 200 | 0.75 | 54.2 | 157.1 | 157.1 | 15710 |
| 300 | 1 | 162.6 | 353.5 | 353.5 | 35350 |

For example, Table 1 shows that for a 100 mm diameter silicon wafer having a thickness of 525 μm the mass of the wafer is 9.5 g. The reduced pressure is trapped in recesses in the carrier. Assuming the recesses take up half of the area of the wafer (and carrier if they are the same size) the reduced pressure acts on an area of 39.3 cm³. If the trapped reduced pressure is 1 mBar less than the surrounding pressure, for example for the wafer and carrier at a nominal atmospheric pressure of 1000 mBar, the pressure trapped in the recesses is 999 mBar, then a maximum mass that can be supported is 39.3 g. This means a one mBar pressure differential can easily support a 100 mm×525 μm silicon wafer.

For each of the four wafers listed in Table 1 a 1 mBar pressure differential is sufficient to support the wafer. Further reducing the pressure to 900 mBar to provide a 100 mBar pressure differential provides an even greater holding force which would be far more than would ever be likely to be required even if many features have already been processed onto the wafer. For the largest vacuum area of 353 cm² a wafer having a mass of 35 kg can be supported.

Table 2 provides an indication of how the mass that can be supported increases as the pressure differential increases from a 1 mBar difference to a 900 mBar difference.

TABLE 2
Variation in pressure pushing the process wafer against
carrier assuming atmospheric pressure outside, and
example of variation in mass supported for 150 mm
diameter wafer with 50% of area as recesses.

| | | | | Maximum |
|---|---|---|---|---|
| | Difference ΔP | | | process |
| | between | | | wafer mass |
| Pressure | recess and | | | supported for |
| inside | outside | Max pressure pushing | | 150 mm |
| recesses of | atmospheric | the process wafer | | diameter |
| carrier wafer | pressure | against the carrier | | wafer |
| mBar | mBar | Nm-2 | kgcm-2 | g |
| 999 | 1 | 100 | 1.00E−03 | 90 |
| 998 | 2 | 200 | 2.00E−03 | 180 |
| 997 | 3 | 300 | 3.00E−03 | 270 |
| 995 | 5 | 500 | 5.00E−03 | 451 |
| 990 | 10 | 1000 | 1.00E−02 | 902 |
| 985 | 15 | 1500 | 1.50E−02 | 1352 |
| 980 | 20 | 2000 | 2.00E−02 | 1803 |
| 975 | 25 | 2500 | 2.50E−02 | 2254 |
| 950 | 50 | 5000 | 5.00E−02 | 4508 |
| 900 | 100 | 10000 | 1.00E−01 | 9016 |
| 800 | 200 | 20000 | 2.00E−01 | 18032 |
| 700 | 300 | 30000 | 3.00E−01 | 27048 |
| 600 | 400 | 40000 | 4.00E−01 | 36064 |
| 500 | 500 | 50000 | 5.00E−01 | 45080 |
| 400 | 600 | 60000 | 6.00E−01 | 54096 |
| 300 | 700 | 70000 | 7.00E−01 | 63112 |
| 200 | 800 | 80000 | 8.00E−01 | 72128 |
| 100 | 900 | 90000 | 9.00E−01 | 81144 |

As mentioned above, FIGS. 1a, 1b and 1c show recesses 15 in the contact surface 17 of the carrier 10. The recesses shown are circular cavities or concentric rings but can be of any arbitrary shape. Much of the above analysis assumes the contact surface 17 comprises 50% by area of recesses. This percentage is useful for the calculations but is not a necessary requirement. In the arrangement of circular cavities in FIG. 1b the hatched area represents the recesses. In this figure around 16% of the area is recessed. In the arrangement of concentric rings of FIG. 1c the recessed area is around 40% of the total area. To achieve a 50% recessed area the diameters of the cavities or rings will need to be adjusted. Alternatively, a greater pressure differential could be used to compensate for the less than 50% recessed area.

The arrangement of recesses does not need to be concentric rings or circular cavities and many other patterns of recesses are possible. The number and shape of the recesses does not directly determine the mass that can be held by the reduced pressure, rather it is the total area of recesses that it determinative. The larger the recessed area, the greater the clamping force. A single large cavity can also be used and this is a conveniently simple recess to produce. Such a cavity would provide, for example, the 50% recessed area and could be produced by a photolithography mask. Alternatively many small recesses may be produced. These small recesses may match raised points of the process wafer topography.

In an embodiment a sealing layer 30 is provided between the carrier 10 and process wafer 20, as shown in FIG. 4. The recesses in the carrier 10 may be produced by applying a photosensitive layer to the carrier 10 and then patterning the recesses in the layer using photolithography. After forming the recesses, the photosensitive surface, such as photoresist will remain and could form a sealing surface. The photoresist will be compliant and deform slightly when the process wafer is moved into contact with it. However, because the photoresist may transfer to the process wafer and then require cleaning it is preferred to use a sealing layer that will not adhere to the process wafer.

In one embodiment a thin sheet of silicone was used as the sealing layer, with a series of holes stamped therein. The holes are stamped coincident with the recesses in the carrier, as shown in FIG. 4. They do not need to be fully coincident but should be at least partly coincident. The silicone sheet is the same diameter as the carrier. The silicone sheet acts as an interlayer between the carrier and process wafer to seal the reduced pressure in the recesses. Other compliant materials may be used for the sealing layer. In one embodiment a single large recess is used and annular shaped silicon sheet is used.

Other examples of materials for the sealing layer include polymers, for example polyimide. Polyimide could be applied directly as a layer to the carrier or used as a sheet material. The most likely fabrication method is to spin on the polymer and produce the recesses or cavities using photolithography, such as using the method described above. However, in an alternative method the polymer may be applied to the carrier and an additional photoresist layer used for patterning of the recesses in the polymer and carrier. This photoresist may be removed before using the carrier.

As mentioned above, when separating the process wafer 20 from the carrier 10, static friction or stiction requires the pressure for release to be lowered by a margin beyond the pressure P1 used when bringing the carrier and process wafer together. When the silicone sheet is used the stiction is relatively high. In the above embodiments we have described pressure differentials of 1 mBar and 100 mBar. For the latter, a release pressure differential of 700 mBar was required to overcome stiction. That is the pressure in the chamber was reduced to 200 mBar, which is a 700 mBar margin beyond the sealing pressure P1 of 900 mBar.

In one embodiment the static friction may be reduced by applying a release material before bringing the carrier and substrate together. The release material may be provided by application as a vapour to the sealing layer, carrier or substrate. The release material lowers the surface energy at the interface to the substrate. An example of a release material is HMDS (hexamethyldisilazane), DDMS (Dimethyldichlorosilane), or TCS (Trichlorosilane) depending on the material to which it is applied, for example the type of polymer used for the sealing or compliant layer.

In a further embodiment a force may be applied to overcome static friction and ease separation of the substrate and carrier when debonding. For example, as described above the carrier 10 may be held by edge clamps to the upper platen 110. Additionally the substrate 20 may be held by an electrostatic chuck at the lower platen 120, such that as the pressure in the chamber is reduced the chucks are moved apart to provide a force to separate the carrier and substrate. In this arrangement the platens may be used in alternative configurations such as by swapping the upper and lower platen, or using them side-by-side.

The problem of static friction or stiction becomes considerable when the thinned substrates or process wafers become particularly thin. For example, for substrates with through silicon vias (TSV), after thinning the substrate thickness could be as low as 20 μm. For a 200 mm diameter wafer a substrate of this thickness has a very small mass, of around 1.5 g. Hence, there is little force due to gravity to remove the substrate from a sealing layer when the carrier is inverted during the de-bond procedure. The small mass of the substrate may result in it being stuck to the sealing layer of the carrier even when the outside chamber pressure is reduced to a value that is less than the pressure used for attaching the substrate to the carrier. However, use of mechanical means for separating the substrate and carrier is preferably avoided when dealing with a 20 μm thick wafer, although the use of vacuum chucks is a practical option. In this case the process wafer becomes clamped to a vacuum chuck which is then moved to an increased distance for the carrier in order to separate the process wafer from the carrier. The level of stiction can be reduced by reducing the contact area between the substrate and polymer sealing layer.

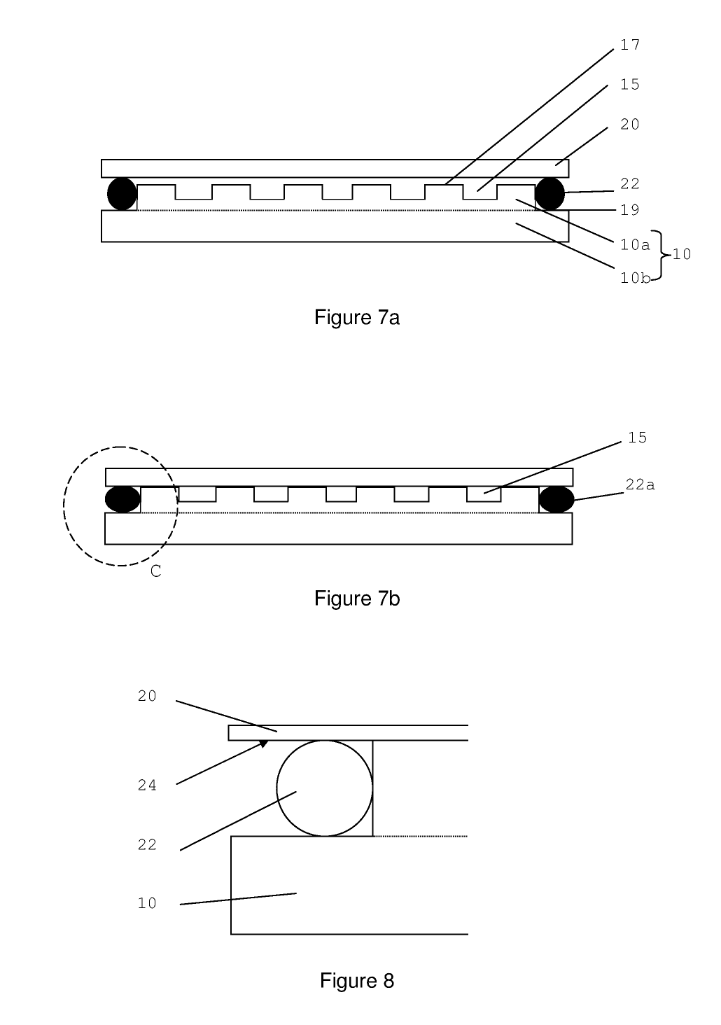

In a preferred embodiment of the invention, as shown in FIGS. 7a and 7b a sealing member is used which does not cover most of the contact surface 17 as is the case for the sealing layer described above. In FIGS. 7a and 7b the orientation of the carrier 10 and substrate 20 is reversed compared to FIG. 4 such that substrate is at the top. The sealing member 22 may be a ring or loop located towards the edge of the carrier 10. Any shape of ring could be used, but since semiconductor substrates are circular a circular ring is preferable. To avoid leakage the ring should be endless, that is it should from a complete loop without breaks. A variety of cross-sections for the ring may be used, but a circular cross-section, namely an o-ring, provides good compressibility to achieve a seal, as well as minimizing contact area with the substrate. When the internal pressure in recesses 15 is lower than the external pressure, the sealing member or o-ring is compressed until the substrate contacts the contact surface 17 of the carrier, as shown in FIG. 7b. As a result the substrate is rigidly clamped to the carrier.

To achieve a good seal that lasts long enough for practical purposes, for example transport, handling and processing, the surfaces that the sealing member is in contact have special requirements. Prior art approaches such as US 2005/0115679 have used a machined groove in the carrier for the seal. Although such a surface allows a vacuum to be retained it is quickly lost because of the surface roughness of the groove. Alternatively, other approaches such as Hurley have used a machined groove with a seal but to maintain the vacuum the cavities in the carrier are connected to a pump system to continuously remove any gas or air ingress. Such a system typically has a surface roughness, Ra, of 0.8 μm (known as an N6 grade surface finish).

In the present invention a longer lasting vacuum can be achieved, without the need for active pumping, by reducing the surface roughness of the surface the sealing member contacts. Instead of using a merely machined surface it has been determined that a polished surface can achieve this.

Experiments using the present invention have shown that the time for the evacuated carrier to leak up to atmospheric pressure is just a few hours for the case where an o-ring sealing member seals against an N6 surface finish (Ra of 0.8 μm), whereas when the o-ring seals against a polished surface, such as <10 nm or more preferably <1 nm Ra polished surface for a standard silicon wafer, the time is extended to several weeks. Pressures used in the chamber for bonding may be 50 kPa or lower, or more preferably greater than 50 kPa (but less than atmospheric pressure) as shown in Table 2.

Machining a groove in silicon and then polishing the bottom surface of the groove to provide the correct surface finish is difficult. The present invention provides a carrier that is formed of two or more carrier wafers. As shown in FIG. 7a the carrier 10 comprises a first carrier wafer 10a and a second carrier wafer 10b of greater diameter than the first. The first and second carrier wafers are bonded together such that the second wafer is left exposed around the circumference. The second carrier wafer has a polished surface and the exposed part of this forms the sealing surface 19 which the sealing member is seated.

In more detail the carrier 10 is manufactured as follows. The example that follows is suitable for handling silicon substrates of 200 mm diameter, but can be adapted to other sizes and materials of substrate. We start with the first carrier wafer 10b which may be a standard 200 mm diameter silicon wafer. The surface finish of SEMI spec polished wafers is <1 nm Ra which makes it a suitable surface in which to seal an o-ring against and achieve non-pumped vacuum integrity. In another embodiment the material is glass that is thermal expansion matched to silicon such as Schott BF33 or MemPax, Corning 7740 or Hoya SD2. A slightly smaller diameter (for example, 190 mm) second carrier wafer 10b is then concentrically bonded to the first carrier wafer 10a. This smaller diameter wafer can also be made of silicon or TCE matched glass. The two wafers are bonded together using either anodic bonding (for silicon-glass combinations) or direct bonding (for silicon-silicon or glass-glass combinations). Such thermally matched carriers can be cycled between room temperature and high (300° C. or more) without causing any significant stress in the carrier or imparting any bending into the carrier as a result of differential thermal expansion between different materials used.

The thickness of the second carrier wafer 10b is preferably slightly less than the sealing member or o-ring thickness, as shown in FIG. 7a, such that once the o-ring is compressed the substrate comes into contact with the contact surface 17 of the first carrier wafer 10a. The difference in thickness between the o-ring and the first carrier wafer 10a therefore needs to be less than the o-ring compression value under atmospheric pressure. A typical compression value for a 3 mm cross-section o-ring is between 100 and 200 μm (depending on the o-ring material and its Shore hardness), and therefore a thickness of 2.85 mm is suitable for the first carrier wafer 10a.

For the embodiment shown in FIGS. 7a and 7b it is preferable to locate the sealing member on the circumference of the substrate. However semiconductor wafers have a notch or flat for alignment and/or identification of the crystal axes. A notch is present in 200 mm and 300 mm diameter silicon wafers, and a flat is present in smaller wafers, such as 2 inch (50.8 mm), 3 inch (76.2 mm), 100 mm, 125 mm and 150 mm diameter silicon wafers. The notch or flat therefore makes it impossible to locate the o-ring at the circumference. Instead it needs to be located, for example a few mm, in from the substrate edge in order to achieve a seal. This produces an overhanging piece of silicon which may be problematic during the wafer thinning step. Some wafers also include secondary flat, for which a similar approach is required.

In the above described arrangement the o-ring makes a circle following the generally circular shape of the substrate and carrier. However, in an alternative arrangement the o-ring could be held such that it forms a circular shape including a flat (known in geometry as a chord). In a further alternative the o-ring could be located at the circumference except where a flat or notch is found. At this point, the o-ring could again take a non-circular shape and be set back from the edge of the substrate. Table 3 below sets out silicon wafer diameters and corresponding primary and secondary flat dimensions as defined by SEMI standards.

TABLE 3
Dimensions in mm for primary and second flat lengths or notches for
silicon wafers. For 150 mm diameter wafer the primary flat length is 57.5 mm if a
secondary flat is also provided, or 47.5 if no secondary flat. 200 m and 300 mm
have a notch instead of a flat and no secondary fiducial.

| | Nominal diameter | | | | | | |
|---|---|---|---|---|---|---|---|
| | 2 inch | 3 inch | 100 mm | 125 mm | 150 mm | 200 mm | 300 mm |
| Actual | 50.80 ± | 76.20 ± | 100.00 ± | 125.00 ± | 150.00 ± | 200.00 ± | 300.00 ± |
| diameter in | 0.38 | 0.63 | 0.50 | 0.50 | 0.20 | 0.20 | 0.20 |
| mm | | | | | | | |
| Notch or flat | Flat | Flat | Flat | Flat | Flat | Notch | Notch |
| Primary flat | 15.88 ± | 22.22 ± | 32.5 ± | 42.5 ± | 57.5 or | N/A | N/A |
| length | 1.65 | 3.17 | 2.5 | 2.5 | 47.5 ± | | |
| | | | | | 2.5 | | |
| Notch depth | N/A | N/A | N/A | N/A | N/A | 1.00 + | 1.00 + |
| from | | | | | | 0.25/ | 0.25/ |
| circumference | | | | | | −0.00 | −0.00 |
| Primary flat | 1.3 | 1.7 | 2.7 | 3.7 | 5.7/3.9 | N/A | N/A |
| inset from | | | | | | | |
| circumference | | | | | | | |
| Secondary | 8.00 ± | 11.18 ± | 18.0 ± | 27.5 ± | 37.5 ± | N/A | N/A |
| flat length | 1.65 | 1.52 | 2.0 | 2.5 | 2.5 | | |
| Secondary | 0.3 | 0.4 | 0.8 | 1.5 | 2.4 | N/A | N/A |
| flat inset from | | | | | | | |
| circumference | | | | | | | |

FIG. 8 shows an expanded view of region identified by “C” in FIG. 7b. When the sealing member is inset from the edge of the substrate an overhang 24 is present. Thinning of the substrate results in this overhang becoming very fragile, with the risk of it breaking during processing.

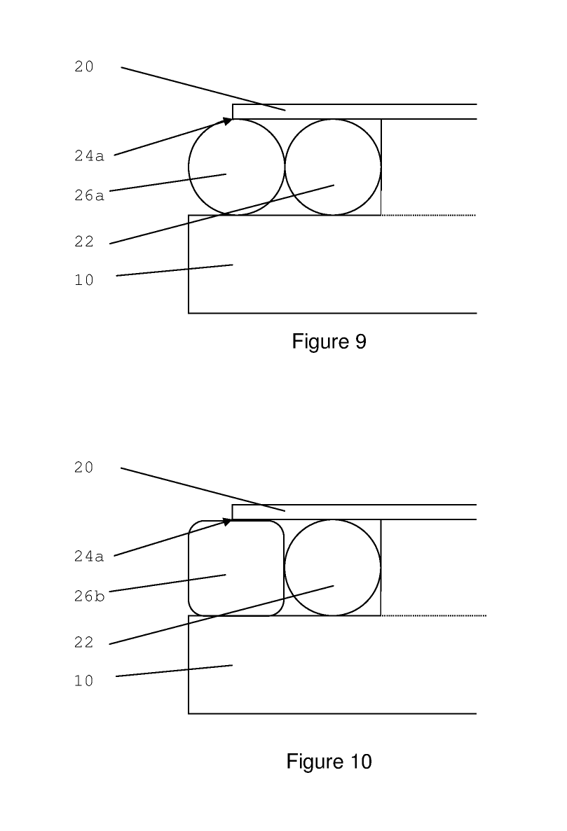

FIG. 9 shows a further embodiment of the carrier. In this embodiment a support member 26a is provided to support the overhang 24a. This support member may also be an o-ring but does not need to provide a seal. As can be seen in FIG. 9, the edge of the substrate sits close to the top of the o-ring to minimize overhang.

A potential problem with the use of the support member is that it obscures the substrate notch or flat which is often used during alignment for photolithography during the post-substrate thinning steps. If the notch or flat is obscured then the photolithography aligner cannot detect the orientation of the wafer and the step therefore fails. This may be overcome by including an aperture (slot, gap, break, void etc) in the support member that allows the aligner optics to perform line of sight detection of the substrate notch or flat, or the outer support ring is made of (or at least partly) a transparent material such as silicone.

FIG. 10 shows a yet further embodiment of the carrier. In this embodiment the support member 26b has a special cross-section such that a flat support surface is provided at the top of the support member 26b. In this way alignment of the substrate to the o-ring is more tolerant. The flat support surface at the top of the special section assists in the support of the thinned wafer and thereby significantly reduces the risk of any wafer damage due to broken overhang during the thinning.

As well as protecting the edge of the substrate from damage, the support member also has an additional benefit. The support member prevents arcing during post-thinning plasma processing steps such as during RIE and deposition.

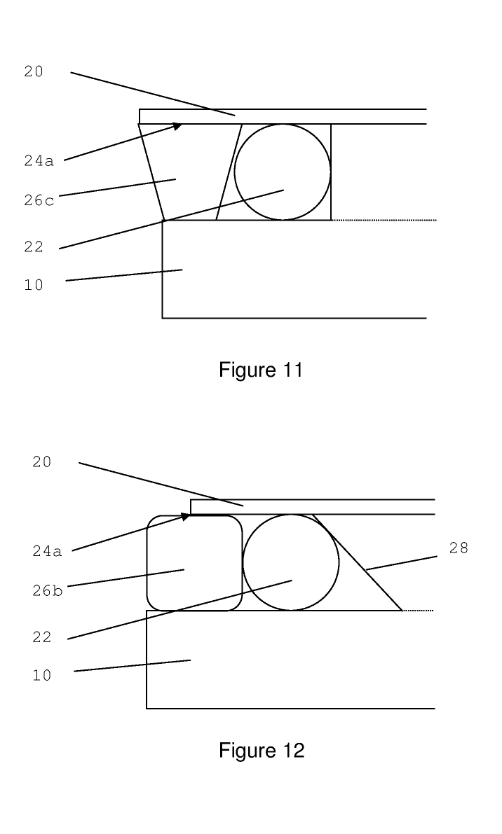

FIG. 11 shows a similar embodiment to FIG. 10 in that the support member has a flat support surface. However, here the support member 26c has a trapezoidal shape such that the carrier diameter is less than the diameter of the substrate. The advantages of the embodiment of FIG. 10 are maintained but greater clearance at the edge of the wafer is provided to ease access and alignment. Again the edge of the substrate can be approximately aligned with the edge of the support member 26c, but since the seal is formed by the o-ring 22, the alignment requirements are not as strict as for the embodiment of FIGS. 7 and 8.

A problem arising from the use of o-rings occurs at the de-bond step when the substrate is released from the carrier. The substrate is released by reducing the pressure in the chamber such that there is a positive internal pressure in the recesses in the carrier forcing the substrate away from the carrier. The process is performed by clamping the carrier to the upper platen of the bond/de-bond apparatus such that the substrate is on the lower side. The substrate is then able to drop, under gravity, and be collected on the lower platen that is positioned to lie in a plane around 1 mm or less below the carrier.

The problem is that when the substrate is released, the o-ring also falls. This can cause a problem for substrate/wafer handling tools when it comes to picking up the de-bonded carrier and substrate. The embodiment of FIG. 12 overcomes this issue problem by including a protrusion in the carrier such that the o-ring is held captive. For example, in the arrangement of FIG. 12 the carrier includes a chamfered edge 28 which has been formed in the first carrier wafer 10a of the carrier before the two carrier wafers have been bonded together. In another method of ensuring the o-ring is retained captive the o-ring has to be sized to be held in tension against the protrusion or step between surfaces. Other shapes of protrusion than the chamfered edge can be used.

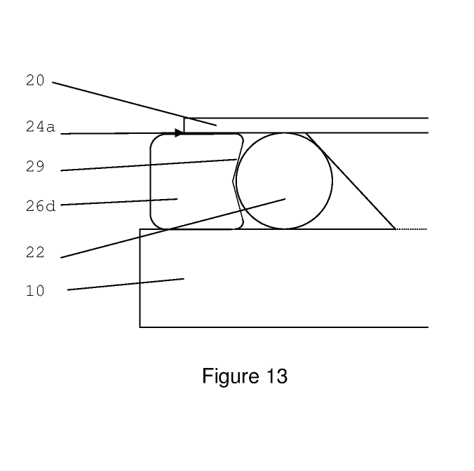

FIG. 13 shows the same retention concept may be applied to the support member 26d. The special cross-section support member engages or mates with the o-ring such that the support member is also not released when the substrate is released. The support member 26d has a surface 29 that is shaped to at least partly engage, in this case the v-shaped jaw shapes engages around part of the circumference of the o-ring.

The materials used for the first and second carrier wafers 10a and 10b are preferably thermally expansion matched to the substrate to be held to avoid bending and stress during processing of the bonded substrate. This can be achieved by using the same material. For example, to hold a silicon substrate the carrier may also be made of silicon.

The sealing member and support member are made of compressible, resilient materials. As described above and shown in FIGS. 7b to 13, the sealing member should contact the contact surface of the carrier when the recesses are evacuated and the pair are moved back to a higher pressure environment. As shown in FIGS. 7a and 7b this results in the sealing member being compressed. The support member 26 therefore should be made of a softer material than the sealing member so that the support member does not prevent compression of the sealing member such that a good seal is formed. Alternatively, or in combination, the support member may be shaped so that it is more easily compressed than the sealing member. This arrangement results in the support member only being compressed as much as the sealing member. As an example of suitable materials, the sealing member and support member are both made of Viton, but a Shore 75 material is used for the sealing ring and a Shore 50 material is used for the support member. Other o-ring sealing materials, e.g. silicone, neoprene, etc., can be used instead of Viton, and different Shore values could also be used, provided that the principle of the sealing member defining the amount of compression is maintained.

In a further embodiment of the invention the process wafer 20 has been processed on its front side resulting in solder bumps and other topography on the front side of the process wafer 20. In this case the recesses in the carrier are arranged such that any raised or sensitive topographical features locate in the recesses on the carrier. As well as protecting the features it also permits the surface of the process wafer to fully contact the carrier such that a seal is formed.

The main application for the vacuum carriers is in supporting substrates for the grinding/polishing steps that are used to thin the substrates, and then further protecting the thinned wafer in the subsequent steps that need to be carried out on the thinned wafer. For 3D integrated circuit applications, the vertical interconnects between the substrates are made using through wafer vias (TSV). There are three possible process options for 3D integration using TSV's. These are known as TSV first, TSV middle and TSV last. All of these require the substrate bonding and thinning step but they each have different post-bond requirements.

The three techniques are summarised in the Table 4 which follows.

TABLE 4
Comparison of three TSV process options, namely
TSV First, TSV Middle and TSV Last.

| TSV First | TSV Middle | TSV Last |
|---|---|---|
| Etch deep silicon | Etch deep silicon | Fabricate transistors |
| cavities | cavities | |
| Insulate cavities | Insulate cavities | Fabricate BEOL |
| | | interconnect |
| Fill cavities with | Fabricate transistors | Bond wafer pair |
| conductor | | |
| Fabricate BEOL | Fill cavities with | Thin back side of |
| interconnect | conductor | wafer |
| Bond wafer pair | Fabricate BEOL | Back side etch deep |
| | interconnect | silicon cavities |
| Thin back side of | Bond wafer pair | Insulate cavities |
| wafer | | |
| Fabricate BEOL | Thin back side of | Fill cavities with |
| interconnect on upper | wafer | conductor |
| wafer | | |
| Etch deep silicon | | |
| cavities | | |

Note:
BEOL = back end of line

Of these three, the TSV last approach is the most demanding on compatibility for downstream processes using the carrier. In addition to the grinding/back-thinning, the carrier has to be compatible with back side etch, cavity insulation, and cavity fill. These steps add the following requirements on to the carrier compatibility:

Immersion of carrier bonded substrate in vacuum; and

High temperature processing up to 300° C.

Prima facie the vacuum immersion requirement would appear to be a problem but provided that the carrier is placed in the vacuum chamber with the substrate facing upwards then vacuum process steps such as deep reactive ion etching (DRIE) and plasma enhanced chemical vapour deposition (PECVD) can be performed without the device wafer separating from the carrier. In this orientation, it is even possible to heat the carrier up to a temperature of 300° C. during the vacuum immersion. This has been successfully demonstrated, but confirms the need for thermal expansion matching of carrier and substrate. Successful demonstration consisted of the carrier still being bonded to the process wafer when removed from the vacuum chamber, plus the ability to subsequently debond via the use of reduced vacuum and increased temperature.

More recently, the Via Middle process has become the most likely contender for future production. In this methodology, as shown in Table 4, the vias are already formed in the substrates and the thinning step (from the opposite face of the substrate) has to reveal the top few microns of the vias. Because grinding is not sufficiently selective, the grinding step is terminated about 10 μm from the tops of the vias and the thinning is completed using either wet or dry etching. If dry etching is used then this places a further compatibility step on the carrier, namely it must continue to hold the substrate when in a high vacuum environment. Although plasma etching is done at pressures of the mBar level, the chamber is normally pumped to a high vacuum before introducing the process gas into the chamber. The present embodiment has been shown to be compatible with immersion in a high vacuum environment even though the pressure external to the carrier is then lower than the pressure at which the substrate was sealed to the carrier. The reason that this works successfully is that the carrier-substrate assembly is loaded into the plasma process chamber with the substrate uppermost and as the chamber pressure is reduced to the level of the internal vacuum (of the carrier) there becomes a point whereby the substrate is only held in place by a combination of gravity and stiction against the sealing member. When the vacuum based process step has been completed and the chamber vented to atmosphere, the pressure differential between the chamber and the carrier is restored thus ensuring that the carrier-substrate assembly can be safely removed from the chamber and progressed to the next process step.

Above we have discussed the possibility of topography of the substrate locating in the recesses. As features on the front side of the substrate (i.e. the side that contacts the carrier) are likely to be small scale but spread across the substrate, whereas the recesses are a much larger scale and possibly to a greater depth than the height of the features, it is preferable to form two sets of recesses in the carrier contact surface. The recesses to accommodate the substrate features are likely to be a shallower depth. For both the TSV Last & TSV Middle approaches to 3D integration, the substrates could already contain front side interconnects and solder balls at the time of the required thinning step. In order to ensure that the substrate contacts the carrier contact surface and therefore can be held rigidly during the grinding step, the array of recesses are machined or etched in to the first carrier wafer 10a such that each protrusion on the device wafer is located within its recess or “receptive cavity”.

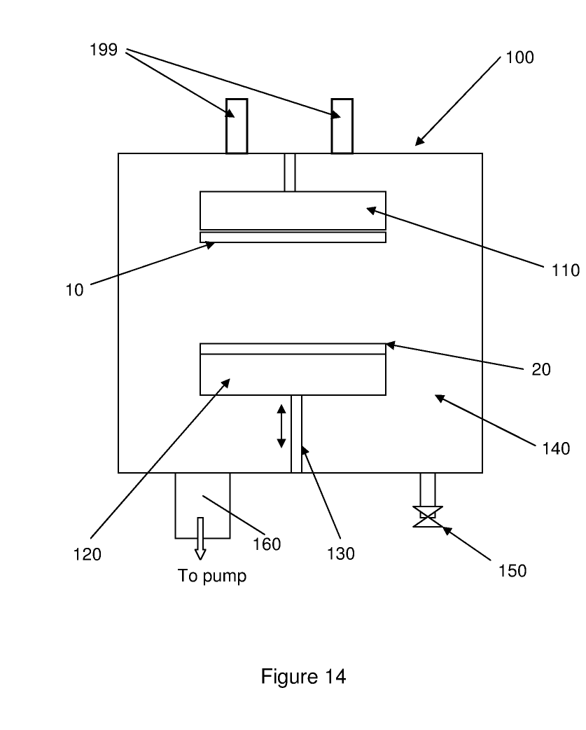

In order to join the substrate and carrier in the required alignment registration to ensure that the surface topography of the substrate is located in the receptive cavities on the carrier, an alignment system is required. FIG. 14 shows an alignment system applied to apparatus corresponding to that described earlier with reference to FIG. 2 for carrying out the bond/de-bond steps.

The alignment system may comprise optics located external to the chamber or a camera located internal or external to the chamber. In order for external optics to be focussed on the interface between the device wafer and the carrier, it is necessary that there are optically transparent viewports in the lid of the chamber, and also that there are corresponding holes in the upper platen enabling the light path between the wafer/carrier and the alignment optics or external camera. Alternatively, materials transparent to optical or infra-red light may be used.

Once the substrate and carrier have been mounted in the process chamber as described earlier, and the chamber pumped down to the required bonding pressure the alignment process can be performed. The alignment process works by bringing the substrate 20 into close proximity with the carrier 10. This is achieved by using the X, Y, Z and θ drive 130, that is three dimensions of linear movement and angular movement such that the carrier and substrate surfaces are aligned parallel. When the substrate is sufficiently close to the carrier (i.e. within the depth of focus of the objective lens of the optics) then the X, y and θ drive mechanisms of the micromanipulators can be used to bring the topographical features on the substrate into alignment with the receptive cavities in the carrier. The Z manipulator can then be used to bring the substrate into contact with the carrier and to apply a force to maintain that contact.

In order to be able to control the level of vacuum held in the recesses of the carrier and hence control the bond/de-bond procedure in a reproducible manner, it is preferred that the alignment and contacting of the substrate to the carrier is performed after the process chamber has been evacuated to the desired pressure. Under such circumstances the value that is read from a pressure gauge, monitoring the pressure of the chamber, will be representative of the pressure that is held in the sealed recesses of the carrier. Otherwise the procedure experiences the same problems as that described in the prior art US 2005/0116579 whereby the two components were contacted before placement in the vacuum chamber and as the chamber is pumped the air in the cavities has difficulty escaping. Under such an arrangement, the pressure displayed on the vacuum gauge bears no relationship with the pressure in the isolated cavities and the process is therefore not controllable other than leaving the system pumping for a very long time in order to ensure complete removal of the trapped air.

With the present embodiment it is possible to rapidly pump down to any defined pressure, perform the alignment and contact the substrate to the carrier. In such a manner the internal pressure of the carrier is well defined and it is a straightforward exercise to define a lower pressure that the chamber has to be pumped down to in order to achieve the subsequent de-bond step after thinning or other processing of the substrate.

A typical bonding pressure is 100 mBar with a corresponding de-bond pressure of 1 mBar. However there is scope to vary these values considerably provided that the de-bond pressure is always lower than the bonding pressure. In some instances it may be necessary to bond the substrate to the carrier at such a low pressure that there is little scope for de-bonding at a lower pressure. Under such circumstances it is possible to achieve the de-bond by pumping down to a similar low pressure and then utilising a heater, incorporated into the platen 110, to increase the temperature and thus the internal pressure of the residual gas in the carrier recesses according to the Gas Laws.

A further optimisation of the carrier is to passivate the material. For example, for a silicon carrier, a passivation layer of silicon dioxide, nitride or oxynitride may be used. Such a passivation layer prevents components of the carrier from being etched during any post-grinding silicon etch of the device wafer. This is important because the wafer thinning step cannot be completely performed using grinding as it is not sufficiently selective to stop once the TSV's have been exposed. Therefore the way that the thinning process is performed is to remove the bulk of the silicon using grinding, and when there is ˜10 um left to remove before reaching the buried vias, switch to either a wet or dry etch process to finish the thinning process. This places further compatibility requirements on the carrier.

The above described process is performed in a chamber in which reduced pressure can be achieved, and a pair of platens is provided of which at least one is movable. Equipment suitable for this is an AML-AWB wafer bonder from Applied Microengineering Limited of Oxfordshire, UK. This equipment conveniently includes an in-situ alignment capability which can be utilized for alignment of the carrier and process wafer. The ability to perform accurate alignment is particularly important when needing to locate topography such as solder balls on the process wafer 20 in recesses 15 in the carrier 10. Other types of equipment may also be used.

Other methods of forming a wafer-carrier pair can also be used. For example, instead of using a pressure differential directly, temperature can be used. In principle after reduced pressure is trapped in recesses between the carrier and process wafer, any technique can be used to separate the pair provided it causes that trapped pressure to be large enough to force the process wafer and carrier apart. In the differential pressure technique, the trapped pressure is greater than the surrounding pressure so the process wafer and carrier are forced apart. In another technique, the carrier and process wafer pair are subjected to heating which raises the temperature of the gas trapped inside the recesses, which produces a corresponding rise in pressure according to the Ideal Gas Law. The increase in pressure causes the recesses to outgas pushing the carrier and process wafer apart. A corresponding approach may also be used when bringing the process wafer and carrier together. For example, the process wafer and carrier are brought together at an elevated temperature T1 and atmospheric pressure. They are held together until the gas in the recesses has cooled. The cooled gas at reduced pressure will hold the process wafer and carrier together. To separate, the pair are heated to an elevated temperature greater than T1 at which the pair were brought together.

Temperature can also be used in another manner for separating the pair. If the carrier and process wafer are different materials with different coefficients of thermal expansion, then separating the process wafer and carrier can be achieved by heating the pair which induces stress and warping forces the two apart.

In a final embodiment, a vacuum is generated in the recesses by condensing steam in the recesses to hold the carrier and process wafer together. In this embodiment steam introduced in to the recesses is condensed after bringing the pair together. Condensation is achieved by cooling the assembly below the boiling point of water or other gaseous solvent.

The above described methods and apparatus provide handling techniques for a wafer such as for thinning a wafer. Specifically the technique provides an example of handling wafers for thinning down to <200 μm, for example down to 100 μm or even as thin as the 10 to 50 μm range, and for subsequent transport of such wafers using a transportable carrier. The wafer is sealed or bonded to the carrier with a vacuum cavity in the carrier to affect a pressure differential with respect to atmosphere. The strength of the seal or bond between the carrier and wafer is high. Furthermore, the same equipment may be used for bonding and de-bonding.

The above described methods and apparatus can be used in semiconductor processes such as 3D integration and wafer level packaging. For 3D integration thinned wafers are important in order to achieve short reliable interconnects between the layer as well as reducing the height and therefore keeping better control of heat dissipation performance by having thinner semiconductor layers for the heat to pass through. The carrier of the present invention, as well as useful in the process of wafer thinning, also provides supporting during via formation, such as by deep reactive ion etching. A fast and effective bonding and debonding technique is necessary for achieving high throughputs of multi layer 3D integrated devices.

The above embodiments mostly consider thinning and other processing of silicon substrates. Although this is by far the largest application, there are also situation whereby one needs to perform similar processing on other materials, e.g. III-V compound wafers such as Gallium Arsenide, and II-VI compound wafers such as Indium Phosphide. For such situations the only essential difference is the material properties of the wafers and we need to suitably modify the carrier—in particular the thermal expansion coefficient. Therefore for III-V applications it is preferable to use a GaAs wafer (or material with similar TCE) as the base layer and bond that to the thicker wafer (either also GaAs or a TCE matched glass). Similarly for II-VI wafers we can use an appropriate II-VI material.

The person skilled in the art will readily appreciate that various modifications and alterations may be made to the above described methods and apparatus without departing from the scope of the appended claims. For example, different shapes, dimensions and materials may be used. Bonding methods may be combined with debonding methods of different embodiments.

1-76. (canceled)

77. A carrier for handling and/or transport of a substrate, such as during processing of the substrate, the carrier comprising:
a contact surface, the contact surface having at least one recess in it, and wherein the recess is for trapping a volume when the contact surface is brought into contact with the substrate, the contact surface for contacting and supporting the substrate;
the contact surface comprising a sealing layer, and wherein the sealing layer is arranged to be compressed to form a seal to the substrate when the substrate is in contact with the contact surface, the seal sealing the trapped volume between the substrate and carrier.

78. The carrier of claim 77, wherein the sealing layer comprises a sheet of compliant material.

79. The carrier of claim 78, wherein the recesses in the carrier comprise a series of holes in the sheet of compliant material.

80. The carrier of claim 79, wherein the holes are stamped into the sheet of compliant material.

81. The carrier of claim 78, wherein the sheet of compliant material is of the same diameter as the carrier.

82. The carrier of claim 79, wherein the recesses in the carrier comprise both recesses in the carrier wafer and a series of holes in the compliant material and wherein the recesses and the holes are at least partly coincident.

83. The carrier of claim 81, wherein the sealing layer has an average roughness, Ra, of less than 100 nm.

84. The carrier of claim 77, further comprising a sealing surface at the periphery of the contact surface and offset from the contact surface; and a sealing member, wherein the sealing member is seated on the sealing surface and arranged to be compressed to form a seal to the substrate when the substrate is in contact with the contact surface, the seal sealing the trapped volume between the substrate and carrier and wherein the sealing surface has an average roughness, Ra, of less than 100 nm.

85. The carrier of claim 84, wherein the sealing member is inset from the edge of the carrier such that notches or flats in the circumference of the substrate to be processed are located peripheral to the sealing member.

86. A method of handling a substrate for processing, the method comprising:
loading the substrate into a chamber;
loading a carrier into the chamber, the carrier having one or more recesses in a contact surface thereof;
reducing the pressure in the chamber to a first pressure;
moving at least one of the substrate and carrier to bring the contact surface of the carrier into contact with the substrate to trap a volume at the first pressure in the one or more recesses between the carrier and substrate;
increasing the pressure in the chamber to a second pressure higher than the first; and
wherein the trapped reduced pressure holds the carrier and substrate together for processing.

87. The method of claim 86, further comprising:
during the step increasing the pressure, holding the substrate and carrier to maintain the trapped reduced pressure in the one or more recesses; and
releasing the hold on the substrate and carrier.

88. The method of claim 86, wherein the carrier comprises a sealing member seated on a sealing surface of the carrier offset from the contact surface and during the step of moving at least one of the substrate and carrier to bring them into contact with each other the sealing member is compressed to form a seal to the substrate and sealing surface to maintain the trapped volume and wherein the sealing surface has an average roughness, Ra, of less than 100 nm.

89. The method of claim 87, wherein the step of holding comprises applying a force to hold the substrate and carrier to maintain the trapped reduced pressure while the pressure in the chamber is increased.

90. The method of claim 87, wherein prior to the further step of reducing the pressure to a third pressure, one of the carrier and substrate are held on a first platen above but facing down to a second platen, such that upon release the other of the substrate and carrier are received by the second platen below the first platen.

91. The method of claim 86, wherein the carrier is clamped to the first platen.

92. The method of claim 86, wherein the recesses in the carrier are aligned with protruding topographic features on the substrate.

93. A method of handling a substrate for processing, the method comprising:
heating a substrate and carrier to a first temperature,
the carrier having one or more recesses in a contact surface thereof;
moving at least one of the substrate and carrier to bring the contact surface of the carrier into contact with the substrate to trap a volume at the first temperature in the one or more recesses between the carrier and substrate; holding the substrate and carrier to maintain the trapped volume in the one or more recesses while reducing the temperature of the carrier and substrate to a second temperature, the trapped volume cooling to a reduced pressure; and releasing the hold on the substrate and carrier, the trapped volume holding the carrier and substrate together for processing.

94. The method of claim 93, further comprising: performing a processing step on the substrate; heating the substrate and carrier to a third temperature higher than the first such that the substrate and carrier are released from each other; and
cooling the substrate and carrier.

95. The method of claim 90, further comprising the step of increasing the temperature of the carrier, thereby increasing the pressure in the trapped volume and thereby assisting the release of the substrate from the carrier when the chamber pressure is reduced.
